(19) United States
(12) Patent Application Publication
(10) Pub. No.: US 2024/0162869 A1
(43) Pub. Date: May 16, 2024

(54) POWER AMPLIFIER CIRCUIT AND POWER AMPLIFIER DEVICE

(71) Applicant: Murata Manufacturing Co., Ltd., Kyoto (JP)

(72) Inventors: Shohei IMAI, Kyoto (JP); Satoshi TANAKA, Kyoto (JP)

(21) Appl. No.: 18/417,311

(22) Filed: Jan. 19, 2024

Related U.S. Application Data
(63) Continuation of application No. PCT/JP2022/038755, filed on Oct. 18, 2022.

(30) Foreign Application Priority Data
Oct. 20, 2021 (JP) 2021-171775

(51) Int. Cl. H03F 3/24; H03F 1/02

(52) U.S. Cl. CPC H03F 3/245; H03F 1/0288; H03F 2200/451

(57) ABSTRACT

A power amplifier circuit includes: a variable power splitter circuit that splits a first signal into a second and a third signal, the third signal being out of phase with the second signal, and increases or decreases first power of the third signal in response to a control signal; a carrier circuit including carrier amplifiers, the carrier circuit amplifies the second signal and output the amplified second signal; a peaking circuit including one or more peaking amplifiers, the peaking circuit amplifies the third signal and outputs the amplified third signal; and a control circuit that outputs to the variable power splitter circuit the control signal based on a saturation level of a target carrier amplifier, the target carrier amplifier being a carrier amplifier positioned closest to the output among the one or more carrier amplifiers in the carrier circuit.

### CROSS REFERENCE TO RELATED APPLICATION

This is a continuation of International Application No. PCT/JP2022/038755 filed on Oct. 18, 2022 which claims priority from Japanese Patent Application No. 2021-171775 filed on Oct. 20, 2021. The contents of these applications are incorporated herein by reference in their entireties.

### BACKGROUND ART

### Technical Field

The present disclosure relates to a power amplifier circuit and a power amplifier device.

When input power to a Doherty amplifier increases, if a peaking amplifier starts amplification before a carrier amplifier reaches saturation, the Doherty amplifier achieves a linear input-output characteristic, while preventing saturation of the carrier amplifier. However, if, for example, manufacturing variations cause a peaking amplifier to be configured to activate at a relatively high level of power, the peaking amplifier starts amplification after the carrier amplifier has reached saturation. As a result, the Doherty amplifier fails to achieve a linear input-output characteristic. In this regard, some Doherty amplifiers include a circuit configured to start amplification with a peaking amplifier when saturation of the carrier amplifier is detected (see, for example, Patent Documents 1 and 2).
Patent Document 1: U.S. Patent Application Publication No. 2016/0241209
Patent Document 2: U.S. Patent Application Publication No. 2020/0028472

### Non Patent Document

Non Patent Document 1: Z. Deng and A. M. Niknejad, “A layout-based optimal neutralization technique for mm-wave differential amplifiers” 2010 IEEE Radio Frequency Integrated Circuits Symposium, 2010, p. 355-358, doi: 10.1109/RFIC.2010.5477367

### BRIEF SUMMARY

In the Doherty amplifier described in Patent Document 1, when saturation of the carrier amplifier is detected, the base current of the peaking amplifier is controlled to increase so as to raise the gain of the peaking amplifier. In the Doherty amplifier described in Patent Document 2, when saturation of the carrier amplifier is not detected, the peaking amplifier remains inactive. When saturation of the carrier amplifier is detected, the gain of the peaking amplifier is controlled to increase so as to activate the peaking amplifier. As described above, in these Doherty amplifiers, when saturation of the carrier amplifier is detected, the bandpass characteristic of the peaking amplifier is increased through control.

In these Doherty amplifiers, a closed circuit is formed by the carrier amplifier, an output coupler, the peaking amplifier, and an input coupler. When the bandpass characteristic of the peaking amplifier increases, a portion of the output from the carrier amplifier can pass through the closed circuit and enter the carrier amplifier. This means that the Doherty amplifier can operate as an oscillation circuit. Even when the Doherty amplifier does not operate as an oscillation circuit, a portion of the output from the carrier amplifier can pass through the closed circuit and overlap the input signal to the carrier amplifier. This overlapping of signals inhibits optimal performance of the Doherty amplifier.

The present disclosure has been made in consideration of the above circumstances, and an object thereof is to provide a power amplifier circuit and a power amplifier device that are capable of achieving a linear input-output characteristic, while suppressing the increase in the bandpass characteristic of a peaking amplifier.

A power amplifier circuit according to an aspect of the present disclosure includes: a variable power splitter circuit configured to split a first signal into a second signal and a third signal, the third signal being out of phase with the second signal, and to increase or decrease first power of the third signal in response to a control signal; a carrier circuit including one or more carrier amplifiers, the carrier circuit being configured to amplify the second signal and output the amplified second signal; a peaking circuit including one or more peaking amplifiers, the peaking circuit being configured to amplify the third signal and output the amplified third signal; and a control circuit configured to output to the variable power splitter circuit the control signal based on a saturation level of a target carrier amplifier, the target carrier amplifier being a carrier amplifier that is positioned closest to the output among the one or more carrier amplifiers in the carrier circuit.

The present disclosure provides the power amplifier circuit, which is capable of achieving a linear input-output characteristic, while suppressing the increase in the bandpass characteristic of the peaking amplifier.

### BRIEF DESCRIPTION OF THE DRAWINGS

FIG. 1 is a circuit diagram of a power amplifier circuit 101.

FIG. 2 is a circuit diagram of a canceller amplifier 501.

FIG. 3 is a circuit diagram of a gain control circuit 604.

FIG. 4 is a diagram illustrating an example of the change in the amount of heat generation in individual amplifiers relative to the output power.

FIG. 5 illustrates an example of the temperature changes in control targets relative to the output power.

FIG. 6 is a circuit diagram of a variable power splitter circuit 302.

FIG. 7 is a circuit diagram of a power amplifier circuit 103.

FIG. 8 is a circuit diagram of a variable power splitter circuit 303.

FIG. 9 is a circuit diagram of a canceller amplifier 511.

FIG. 10 is a circuit diagram of a power amplifier circuit 104.

FIG. 11 is a circuit diagram of a power amplifier circuit 105.

FIG. 12 is a circuit diagram of a power amplifier circuit 106.

FIG. 13 is a circuit diagram of a power amplifier circuit 107.

FIG. 14 is a circuit diagram of a power amplifier circuit 108.

### DETAILED DESCRIPTION

Hereinafter, embodiments of the present disclosure will be described in detail with reference to the drawings. The same elements are assigned the same reference numerals, and redundant descriptions will be omitted as much as possible.

### First Embodiment

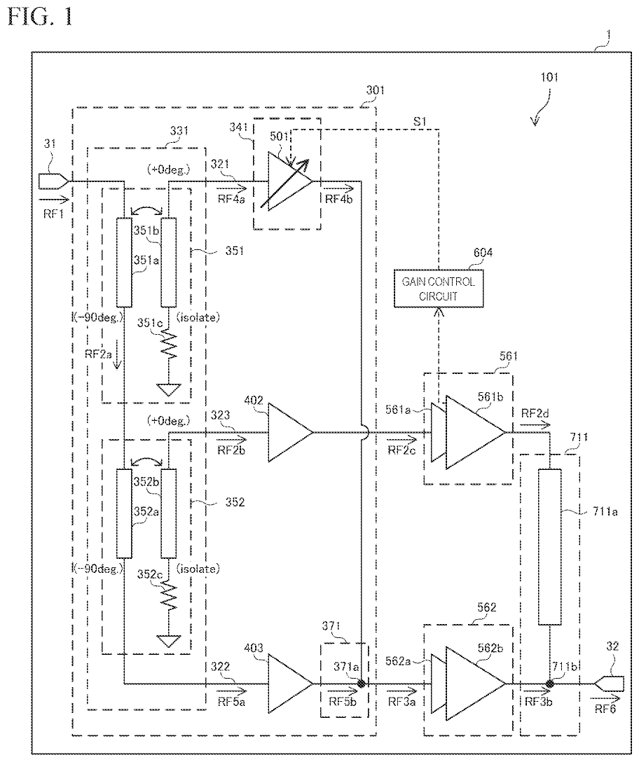

A power amplifier circuit according to a first embodiment will be described. FIG. 1 is a circuit diagram of a power amplifier circuit 101. Phase angles enclosed in parentheses are indicated in some of the drawings. The phases correspond to the relative phases between the terminals of individual components.

As illustrated in FIG. 1, the power amplifier device includes a compound semiconductor 1. The compound semiconductor 1 is manufactured by an integrated circuit process using as a material, for example, a semiconductor primarily containing a compound of a group III element and a group V element. This semiconductor is made of, for example, gallium arsenide (GaAs) as a principal component. The power amplifier circuit 101 is formed in the compound semiconductor 1.

The power amplifier circuit 101 is a Doherty amplifier circuit for amplifying a signal RF1 (first signal), which is a radio frequency (RF) signal, and outputting an amplified signal RF6. The power amplifier circuit 101 includes a variable power splitter circuit 301, a carrier circuit 561, a peaking circuit 562, a gain control circuit 604, and a combiner circuit 711.

First, each circuit in the power amplifier circuit 101 will be outlined. The variable power splitter circuit 301 in the power amplifier circuit 101 is operable to split the signal RF1, which is supplied through an input terminal 31, into a signal RF2c (second signal) and a signal RF3a (third signal). The signal RF3a is out of phase with the signal RF2c.

The carrier circuit 561 includes one or more carrier amplifiers. The carrier circuit 561 is operable to amplify the signal RF2c supplied from the variable power splitter circuit 301 and output an amplified signal RF2d, which is obtained by amplifying the signal RF2c.

The peaking circuit 562 includes one or more peaking amplifiers. The peaking circuit 562 is operable to amplify the signal RF3a supplied from the variable power splitter circuit 301 and output an amplified signal RF3b, which is obtained by amplifying the signal RF3a.

The combiner circuit 711 is operable to combine the amplified signal RF2d from the carrier circuit 561 and the amplified signal RF3b from the peaking circuit 562 and output the amplified signal RF6, which is the amplified signal of the signal RF1, to an output terminal 32.

The gain control circuit 604 is operable to output a control signal S1 to the variable power splitter circuit 301, based on the saturation level of the carrier amplifier that is positioned closest to the output among the one or more carrier amplifiers in the carrier circuit 561.

The variable power splitter circuit 301 is able to increase or decrease the power (first power) of the signal RF3a in response to the control signal S1 from the gain control circuit 604.

Each circuit in the power amplifier circuit 101 will be detailed below. The variable power splitter circuit 301 includes a first wire 321, a second wire 322, a third wire 323, a splitter circuit 331, a bandpass characteristic altering circuit 341, a combiner circuit 371, and buffer amplifiers 402 and 403.

The splitter circuit 331 is operable to split the signal RF1, which is supplied through the input terminal 31, into a signal RF2b (second signal), a signal RF4a (fourth signal), and a signal RF5a (fifth signal). The signal RF4a is out of phase with the signal RF2b by approximately 90 degrees. The signal RF5a is substantially in antiphase with the signal RF4a.

In the present embodiment, the splitter circuit 331 includes 90-degree couplers 351 and 352. The 90-degree coupler 351 includes wires 351a and 351b and a resistance element 351c. The 90-degree coupler 352 includes wires 352a and 352b and a resistance element 352c. The wires 351a, 351b, 352a, and 352b are, for example, quarter wavelength lines. The combiner circuit 371 includes a node 371a.

The first wire 321 couples the 90-degree coupler 351 to the node 371a in the combiner circuit 371. The second wire 322 couples the 90-degree coupler 352 to the node 371a. The third wire 323 couples the 90-degree coupler 352 to the carrier circuit 561.

The wire 351a in the 90-degree coupler 351 has a first end coupled to the input terminal 31, and a second end. The wire 351b has a first end coupled to the node 371a via the first wire 321 and a second end coupled to the ground via the resistance element 351c. The wire 351b is electromagnetically coupleable to the wire 351a.

When the signal RF1 is supplied to the first end of the wire 351a, a signal RF2a, which has a phase delayed by approximately 90° relative to the signal RF1, is output from the second end of the wire 351a, and the signal RF4a, which is substantially in phase with the signal RF1, is output from the first end of the wire 351b. The second end of the wire 351b serves as an isolation port with respect to the first end of the wire 351a.

The wire 352a in the 90-degree coupler 352 has a first end coupled to the second end of the wire 351a and a second end coupled to the node 371a via the second wire 322. The wire 352b has a first end coupled to the carrier circuit 561 via the third wire 323 and a second end coupled to the ground via the resistance element 352c. The wire 352b is electromagnetically coupleable to the wire 352a.

When the signal RF2a is supplied to the first end of the wire 352a, the signal RF5a, which has a phase delayed by approximately 90° relative to the signal RF2a, is output from the second end of the wire 352a, and the signal RF2b, which is substantially in phase with the signal RF2a, is output from the first end of the wire 352b. The second end of the wire 352b serves as an isolation port with respect to the first end of the wire 352a.

Overall, the phase of the signal RF2b is delayed by approximately 90 degrees relative to the signal RF4a, and the phase of the signal RF5a is delayed by approximately 180 degrees relative to the phase of the signal RF4a. In other words, the signal RF4a is out of phase with the signal RF2b by approximately 90 degrees, and the signal RF5a is substantially in antiphase with the signal RF4a. In this specification, the term “approximately X degrees” refers to the angles that range between the angle of X degrees plus 45 degrees and the angle of X degrees minus 45 degrees.

The signals RF4a, RF5a and RF2b from the splitter circuit 331 are respectively transmitted through the first wire 321, the second wire 322, and the third wire 323.

The bandpass characteristic altering circuit 341 is provided in the first wire 321. The bandpass characteristic altering circuit 341 is operable to alter the bandpass characteristic of the signal RF4a while passing through the first wire 321, in response to the control signal S1 from the gain control circuit 604.

In the present embodiment, the bandpass characteristic altering circuit 341 includes a canceller amplifier 501 (variable gain amplifier). The gain of the canceller amplifier 501 is variable in response to the control signal S1.

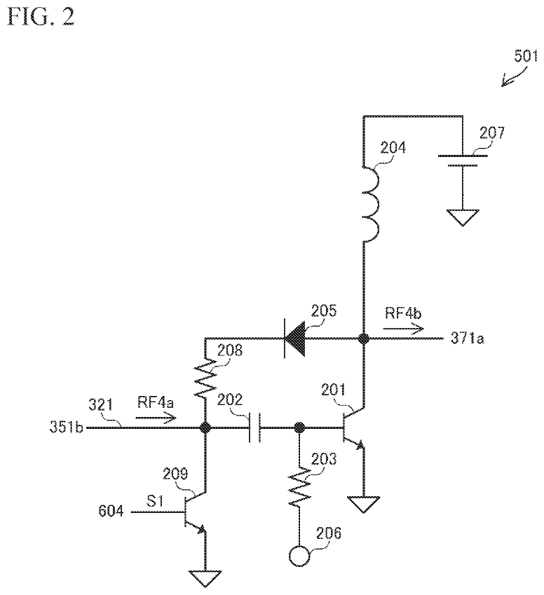

FIG. 2 is a circuit diagram of the canceller amplifier 501. As illustrated in FIG. 2, the canceller amplifier 501 includes transistors 201 and 209, a capacitor 202, resistance elements 203 and 208, an inductor 204, a diode 205, and a voltage supply 207.

In the present embodiment, the transistors, for example the transistors 201 and 209, are bipolar transistors such as heterojunction bipolar transistors (HBTs). The transistors such as the transistors 201 and 209 may be implemented using other transistors such as field-effect transistors (MOSFET: Metal-oxide-semiconductor Field-Effect Transistor). In these cases, base, collector, and emitter are respectively considered equivalent to gate, drain, and source.

The capacitor 202 has a first end coupled to the first end of the wire 351b in the 90-degree coupler 351, and a second end. The resistance element 203 has a first end coupled to a bias supply terminal 206, and a second end. A bias current or bias voltage from the transistor 201 can be supplied to the bias supply terminal 206.

The transistor 201 has a base coupled to the second end of the capacitor 202 and the second end of the resistance element 203, a collector coupled to the node 371a, and an emitter coupled to the ground. The inductor 204 has a first end coupled to the collector of the transistor 201 and a second end coupled to a positive electrode of the voltage supply 207. The negative electrode of the voltage supply 207 is coupled to the ground.

A bias current or bias voltage can be supplied to the base of the transistor 201 from the bias supply terminal 206 through the resistance element 203. A voltage can be applied to the collector of the transistor 201 from voltage supply 207 through the inductor 204. The transistor 201 is operable to amplify the signal RF4a, which is input to the base, and to output a signal RF4b, which is obtained by amplifying the signal RF4a, from the collector to the node 371a.

The diode 205 has an anode coupled to the collector of the transistor 201 and a cathode coupled to the first end of the capacitor 202 via the resistance element 208. A diode-connected transistor may be provided instead of the diode 205.

The transistor 209 has a collector coupled to the first end of the capacitor 202, a base coupled to the gain control circuit 604, and an emitter coupled to the ground.

(Amplification by Canceller Amplifier 501)

The transistor 201 is operable as a common-emitter circuit with the collector serving as the output. The transistor 201 outputs the signal RF4b, which is an amplified inverted form of the signal RF4a, to the node 371a.

The diode 205 and the resistance element 208 are provided between the collector and the base of the transistor 201, forming a feedback path from the collector to the base of the transistor 201. As a result, the signal RF4b outputted from the collector of the transistor 201 is fed back to the base of the transistor 201 through the diode 205 and the resistance element 208.

Because the polarity of the voltage of the signal RF4a and the polarity of the voltage of the signal RF4b are opposite to each other, the signal RF4b fed back to the base of the transistor 201 weakens the power of the signal RF4a. In other words, the gain of the transistor 201 is lowered by the feedback of the signal RF4b from the collector to the base of the transistor 201.

The diode 205 has the property that the equivalent resistance varies with the current flowing in the diode 205. In the canceller amplifier 501, the collector current of the transistor 209 can be controlled via the control signal S1 that is supplied from the gain control circuit 604 to the base of the transistor 209. By increasing or decreasing the collector current of the transistor 209, the current flowing in the diode 205 can be increased or decreased.

By controlling the current flowing in the diode 205 via the control signal S1, the equivalent resistance of the diode 205 can be controlled. As such, the amount of feedback of the signal RF4b from the collector to the base of the transistor 201 is controlled. As a result, the gain of the transistor 201 is controlled.

As illustrated in FIG. 1, the buffer amplifiers 402 and 403 are respectively provided in the third wire 323 and the second wire 322. The buffer amplifier 402 has an input terminal and an output terminal. The input terminal of the buffer amplifier 402 is coupled to the first end of the wire 352b in the 90-degree coupler 352. The signal RF2b can be supplied to the input terminal. The output terminal of the buffer amplifier 402 is coupled to the carrier circuit 561. The signal RF2c obtained by amplifying the signal RF2b can be output from the output terminal of the buffer amplifier 402. Specifically, in the buffer amplifier 402, the signal RF2b can be inverted and amplified by, for example, a transistor configured to operate as a common-emitter circuit with the collector serving as the output and can be output from the output terminal as the signal RF2c.

The buffer amplifier 403 has an input terminal and an output terminal. The input terminal is coupled to the second end of the wire 352a in the 90-degree coupler 352. The signal RF5a can be supplied to the input terminal. The output terminal is coupled to the node 371a. The signal RF5b obtained by amplifying the signal RF5a can be output from the output terminal of the buffer amplifier 403. Specifically, in the buffer amplifier 403, the signal RF5a can be inverted and amplified by, for example, a transistor configured to operate as a common-emitter circuit with the collector serving as the output and can be output from the output terminal as the signal RF5b.

At the node 371a in the combiner circuit 371, the signal RF4b after passing through the first wire 321 and the signal RF5b after passing through the second wire 322 can be combined to generate the signal RF3a.

The power of the signal RF3a depends on the gain of the canceller amplifier 501. Specifically, because the phase of the signal RF5b is delayed by 180 degrees relative to the signal RF4b, the signal RF4b decreases the amplitude of the signal RF5b when the signals RF4b and RF5b are combined at the node 371a.

As a result, as the gain of the canceller amplifier 501 increases, the amplitude of the signal RF4b increases; consequently, the power of the signal RF3a decreases. Conversely, as the gain of the canceller amplifier 501 decreases, the amplitude of the signal RF4b decreases; consequently, the power of the signal RF3a increases.

The carrier circuit 561 includes a driver-stage carrier amplifier 561a and a power-stage carrier amplifier 561b. The power-stage carrier amplifier 561b is cascade-connected to the driver-stage carrier amplifier 561a. The driver-stage carrier amplifier 561a has an input terminal coupled to the output terminal of the buffer amplifier 402 in the variable power splitter circuit 301, and an output terminal. The power-stage carrier amplifier 561b has an input terminal coupled to the output terminal of the driver-stage carrier amplifier 561a, and an output terminal.

The signal RF2c can be supplied from the buffer amplifier 402 to the input terminal of the driver-stage carrier amplifier 561a. The amplified signal RF2d obtained by amplifying the signal RF2c by the driver-stage carrier amplifier 561a and the power-stage carrier amplifier 561b can be output from the output terminal of the power-stage carrier amplifier 561b.

The peaking circuit 562 includes a driver-stage peaking amplifier 562a and a power-stage peaking amplifier 562b. The power-stage peaking amplifier 562b is cascade-connected to the driver-stage peaking amplifier 562a. The driver-stage peaking amplifier 562a has an input terminal coupled to the node 371a in the variable power splitter circuit 301, and an output terminal. The power-stage peaking amplifier 562b has an input terminal coupled to the output terminal of the driver-stage peaking amplifier 562a and an output terminal coupled to the output terminal 32 via a node 711b in the combiner circuit 711.

The signal RF3a can be supplied to the input terminal of the driver-stage peaking amplifier 562a through the node 371a. The amplified signal RF3b obtained by amplifying the signal RF3a by the driver-stage peaking amplifier 562a and the power-stage peaking amplifier 562b can be output from the output terminal of the power-stage peaking amplifier 562b.

The combiner circuit 711 includes a quarter wavelength line 711a and the node 711b. The quarter wavelength line 711a has a first end coupled to the output terminal of the power-stage carrier amplifier 561b and a second end coupled to the node 711b. The quarter wavelength line 711a is operable to delay the phase of the amplified signal RF2d supplied from the power-stage carrier amplifier 561b by approximately 90 degrees.

Because the phase of the amplified signal RF2d has been delayed by approximately 90 degrees by the quarter wavelength line 711a, in the state in which the phase of the amplified signal RF2d is substantially aligned with the phase of the amplified signal RF3b, the amplified signals RF2d and RF3b are combined at the node 711b to generate the amplified signal RF6. In the present specification, when two signals are referred to as having phases “substantially aligned”, this means that the magnitude of the phase difference between the two signals is less than 45 degrees.

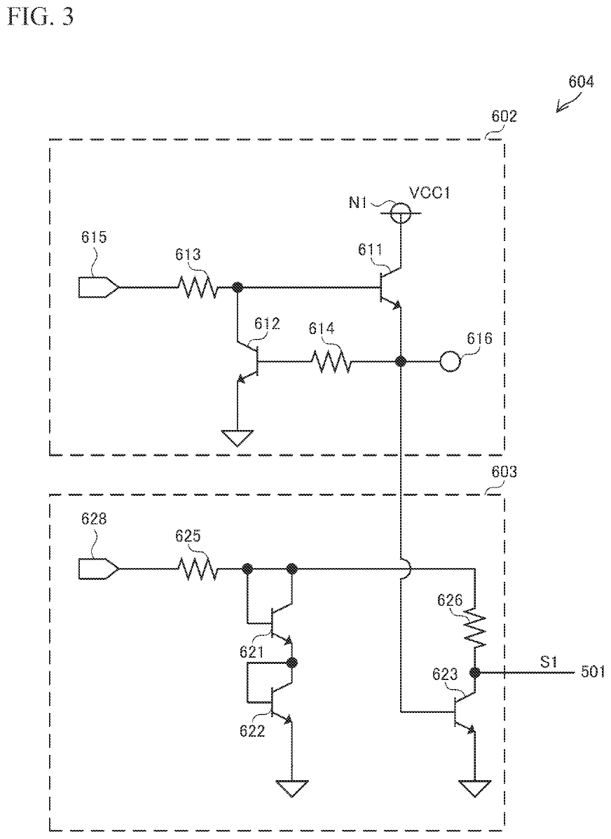

FIG. 3 is a circuit diagram of the gain control circuit 604. As illustrated in FIG. 3, the gain control circuit 604 includes a bias supply circuit 602 and a variable-gain amplifier (VGA) control circuit 603. The bias supply circuit 602 includes transistors 611 and 612 and resistance elements 613 and 614. The VGA control circuit 603 includes transistors 621, 622, and 623 and resistance elements 625 and 626.

The gain control circuit 604 is operable to, when the power-stage carrier amplifier 561b (hereinafter sometimes referred to as the target carrier amplifier 561b) that is the one closer to the output of the two carrier amplifiers in the carrier circuit 561 (see FIG. 1) becomes saturated, output to the canceller amplifier 501 the control signal S1 for reducing the gain of the canceller amplifier 501 in the variable power splitter circuit 301. As used herein, the expression “when a target carrier amplifier becomes saturated” refers to the period from the onset of saturation in the target carrier amplifier until the target carrier amplifier is fully saturated.

The bias supply terminal 616 is coupled to, for example, the base of an amplifier transistor (not illustrated in the drawings) included in the target carrier amplifier 561b. The bias supply circuit 602 is operable to supply a base potential that is suitable for the target carrier amplifier 561b through the bias supply terminal 616 to the target carrier amplifier 561b. Specifically, for example, a control current for controlling the bias for the target carrier amplifier 561b can be supplied from outside to a bias control signal input terminal 615. A supply voltage VCC1 can be supplied from outside to a supply voltage feeding node N1.

The transistor 611 has a collector coupled to the supply voltage feeding node N1, a base coupled to the bias control signal input terminal 615 via the resistance element 613, and an emitter coupled to the bias supply terminal 616.

The transistor 612 has a collector coupled to the base of the transistor 611, a base coupled to the emitter of the transistor 611 via the resistance element 614, and an emitter coupled to the ground.

A bias voltage obtained by adding a base-emitter voltage Vbe of the transistor 612 and the voltage across the terminals of the resistance element 614 can be supplied to the target carrier amplifier 561b through the bias supply terminal 616.

When the target carrier amplifier 561b becomes saturated, the base current flowing from the bias supply terminal 616 to the target carrier amplifier 561b increases. At this time, the bias voltage at the bias supply terminal 616 decreases. This means that the decrease in the bias voltage at the bias supply terminal 616 corresponds to a detection signal for detecting saturation of the target carrier amplifier 561b.

The VGA control circuit 603 is operable to generate the control signal S1 for controlling the gain of the canceller amplifier 501 based on the detection signal and supply the control signal S1 to the transistor 209 in the canceller amplifier 501.

Specifically, the transistor 621 is diode-connected. The transistor 621 has a collector coupled to a VGA control voltage input terminal 628 via the resistance element 625, and an emitter. The transistor 622 is diode-connected. The transistor 622 has a collector coupled to the emitter of the transistor 621, and an emitter coupled to the ground.

The resistance element 626 has a first end coupled to the collector of the transistor 621 and a second end. The transistor 623 has a collector coupled to the second end of the resistance element 626 and the base of the transistor 209 in the canceller amplifier 501 (see FIG. 2), a base coupled to the emitter of the transistor 611, and an emitter coupled to the ground.

A voltage for generating a reference voltage can be supplied from outside to the VGA control voltage input terminal 628. Both the transistors 621 and 622 function as diodes. This configuration yields a voltage drop that corresponds to two diodes, across the paths between the collector and the emitter of the transistor 621 and between the collector and the emitter of transistor 622. This means that when the ground serves as a reference, the voltage at the collector of the transistor 621, which is the reference voltage, is the voltage that exhibits a magnitude corresponding to the voltage drop across two diodes.

The voltage at the collector of the transistor 623 is the voltage obtained by subtracting the voltage across the terminals of the resistance element 626 from the reference voltage. A current corresponding to the detection signal supplied to the base of the transistor 623 can flow in the resistance element 626.

Specifically, when the target carrier amplifier 561b becomes saturated, the voltage value of the detection signal decreases. As a result, the current flowing to the collector of the resistance element 626 and the transistor 623 decreases. The voltage across the terminals of the resistance element 626 thus decreases, and the collector voltage of the transistor 623, that is, the control signal S1, rises. In other words, when the target carrier amplifier 561b becomes saturated, the voltage of the control signal S1 outputted by the VGA control circuit 603 to the transistor 209 in the canceller amplifier 501 (see FIG. 2) increases.

The VGA control circuit 603 may additionally include an inverting amplifier circuit coupled between the transistor 623 and the canceller amplifier 501. With this configuration, the control signal S1 can be decreased when the target carrier amplifier 561b becomes saturated.

As illustrated in FIG. 2, in the canceller amplifier 501, when the voltage of the control signal S1 rises, the collector current of the transistor 209 and the current flowing in the diode 205 increase, and the gain of the transistor 201 decreases. As a result, the power of the signal RF4b outputted from the canceller amplifier 501 decreases.

As described above, the phase of the signal RF5b is delayed by approximately 180 degrees relative to the signal RF4b. When the power of the signal RF4b decreases, cancellation of the signal RF5b by the signal RF4b is also suppressed, and the power of the signal RF3a increases. In other words, when the target carrier amplifier 561b becomes saturated, the power of the signal RF3a supplied to the peaking circuit 562 increases.

(Effects)

FIG. 4 is a diagram illustrating an example of the change in the amount of heat generation in each amplifier relative to the output power. In FIG. 4, the horizontal axis represents the output power of the power amplifier circuit 101 or the output power of the Doherty amplifier described in Patent Document 1 (hereinafter sometimes referred to as the comparison target amplifier); the vertical axis represents the amount of heat generation by each amplifier.

As illustrated in FIG. 4, as the output power of the power amplifier circuit 101 increases, the amount of heat generation by the target carrier amplifier 561b in the power amplifier circuit 101 greatly increases as illustrated by a curved line C1. In other words, the increase in the amount of heat generation by the target carrier amplifier 561b depends on the saturation level of the target carrier amplifier 561b. The same holds for the amount of heat generation by the carrier amplifier in the comparison target amplifier.

When the output power of the comparison target amplifier increases, and saturation of the carrier amplifier is detected, the comparison target amplifier provides control to change the bias point to increase the gain of the peaking amplifier. This means that the control target in the comparison target amplifier is the peaking amplifier. When saturation of the carrier amplifier is detected, the power consumption of the control target increases. The Doherty amplifier described in Patent Document 2 also achieves the same effect.

Thus, the amount of heat generation by the control target of the comparison target amplifier increases with the saturation level of the carrier amplifier, as illustrated by a curved line C3.

By contrast, when the output power of the power amplifier circuit 101 increases, and the target carrier amplifier 561b becomes saturated, the power amplifier circuit 101 provides control to reduce the gain of the canceller amplifier 501. This means that the control target in the power amplifier circuit 101 is the canceller amplifier 501. When saturation of the target carrier amplifier 561b is detected, the power consumption of the control target decreases.

As a result, the amount of heat generation by the control target of the power amplifier circuit 101 decreases with the saturation level of the power-stage carrier amplifier 561b, as illustrated by a curved line C2.

When the power amplifier circuit 101 is observed from a macroscopic perspective, when the target carrier amplifier 561b becomes saturated, the temperature rises due to the increase in power consumption. This temperature rise is largely caused by the increase in power consumption in the target carrier amplifier 561b. In other words, as a result of the heat generated in the target carrier amplifier 561b conducting throughout the circuitry, the temperature of the power amplifier circuit 101 increases.

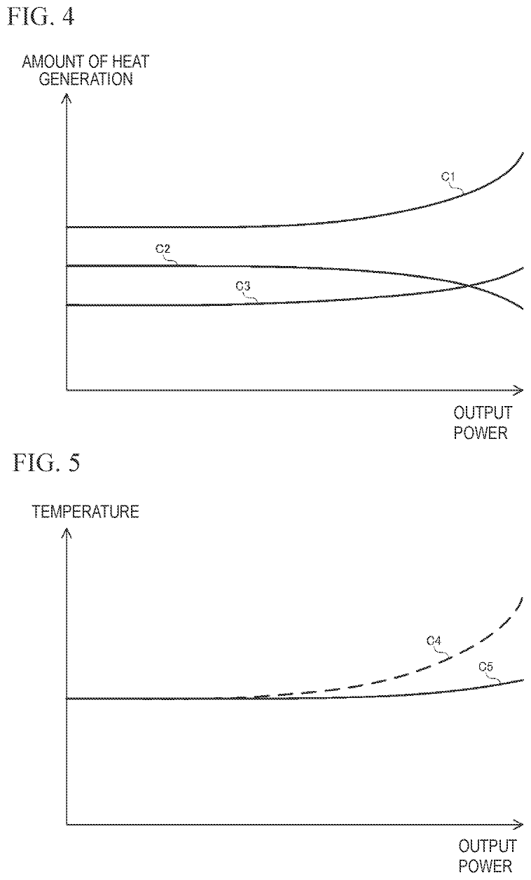

FIG. 5 illustrates an example of the temperature changes in the control targets relative to the output power. In FIG. 5, the horizontal axis represents the output power of the power amplifier circuit 101 or the output power of the comparison target amplifier; the vertical axis represents the temperature of the control targets.

As illustrated in FIG. 5, in the comparison target amplifier, as the output power of the comparison target amplifier increases, the amount of heat generation by the carrier amplifier increases, and the amount of heat generation by the peaking amplifier as the control target also increases. Thus, the temperature of the control target greatly increases with the saturation level of the carrier amplifier, as illustrated by a curved line C4.

By contrast, in the power amplifier circuit 101, as the output power of the power amplifier circuit 101 increases, the amount of heat generation by the target carrier amplifier 561b increases, whereas the amount of heat generation by the canceller amplifier 501 as the control target decreases. As a result, although the temperature of the control target rises with the saturation level of the target carrier amplifier 561b as illustrated by a curved line C5, the temperature rise in the control target of the power amplifier circuit 101 is suppressed as compare to the temperature rise in the control target of the comparison target amplifier. This means that when the output power of the power amplifier circuit 101 increases, the power amplifier circuit 101 suppresses the temperature rise in the control target.

Here, the problems caused by the temperature rise in the control target of the comparison target amplifier will be detailed from a temporal perspective.

In the comparison target amplifier, when saturation of the carrier amplifier is detected, control is provided to increase the gain of the peaking amplifier. The amount of heat generation by the peaking amplifier begins to increase immediately after control to increase the gain is performed. Accordingly, the temperature of the peaking amplifier begins to rise immediately after saturation of the carrier amplifier is detected.

The amount of heat generation by the carrier amplifier and the temperature of the carrier amplifier begin to increase with the output power before the carrier amplifier becomes saturated. The amount of heat generation during saturation of the carrier amplifier begins to greatly increase immediately after the carrier amplifier becomes saturated. Accordingly, the temperature of the carrier amplifier also begins to greatly rises immediately after the carrier amplifier becomes saturated. The temperature rise in the carrier amplifier is more than the temperature rise in the peaking amplifier.

When the carrier amplifier is hotter than the peaking amplifier, heat is transferred from the carrier amplifier at a higher temperature to the peaking amplifier at a lower temperature. This heat transfer takes a certain length of time (for example, a few milliseconds).

Overall, the temperature of the peaking amplifier begins to rise immediately after the carrier amplifier becomes saturated; afterward, the temperature of the peaking amplifier further increases due to heat transferred from the carrier amplifier.

When the temperature rise in the carrier amplifier changes as described above, the control in the comparison target amplifier is performed in the following manner.

At the timing of the onset of saturation of the carrier amplifier, the bias point is raised such that a sufficient amount of control is provided for the peaking amplifier, in other words, the peaking amplifier achieves a sufficient amount of gain increase; as a result, saturation of the carrier amplifier is resolved (step St1).

Generally, as temperature increases, gain decreases. Hence, when the temperature of the peaking amplifier further increases due to heat transferred from the carrier amplifier, the gain of the peaking amplifier decreases. As a result, the amount of control on the peaking amplifier becomes insufficient (step St2).

When the amount of control on the peaking amplifier becomes insufficient, the carrier amplifier becomes saturated again (step St3). Thus, the bias point of the peaking amplifier is raised (step St1).

This means that because the amount of control becomes insufficient due to the temperature fluctuations in the peaking amplifier, the operations in steps St1 to St3 need to be repeated; as a result, a longer time is needed until saturation of the carrier amplifier is resolved with stability.

In addition, the repetition of the operations in steps St1 to St3 increases the power consumption in the comparison target amplifier. This increase in power consumption can cause thermal runaway in the comparison target amplifier, potentially resulting in damage in the comparison target amplifier.

By contrast, the power amplifier circuit 101 begins control to lower the gain of the canceller amplifier 501, for example, from the timing of the onset of saturation of the target carrier amplifier 561b. By providing this control, the output power from the driver-stage peaking amplifier 562a and the power-stage peaking amplifier 562b increases, and saturation in the target carrier amplifier 561b is accordingly resolved.

Thereafter, when the temperature of the canceller amplifier 501 increases due to heat transferred from the target carrier amplifier 561b, the temperature rise further decreases the gain of the canceller amplifier 501. As a result, the output power from the driver-stage peaking amplifier 562a and the power-stage peaking amplifier 562b further increases.

This means that saturation of the target carrier amplifier 561b is more relaxed by the temperature rise in the canceller amplifier 501 due to heat transferred from the target carrier amplifier 561b. This configuration thus shortens the time to stably resolve saturation of the target carrier amplifier 561b and also inhibits the target carrier amplifier 561b from becoming saturated again. The control to reduce the gain of the canceller amplifier 501 suppresses the increase in power consumption in the power amplifier circuit 101, hindering thermal runaway in the power amplifier circuit 101. This configuration thus inhibits damage to the power amplifier circuit 101.

### Second Embodiment

A variable power splitter circuit according to a second embodiment will be described. In the second embodiment, descriptions of the features common to the first embodiment will not be repeated, and only different features will be explained. In particular, the same effects achieved by the same configurational features will not be described in every embodiment.

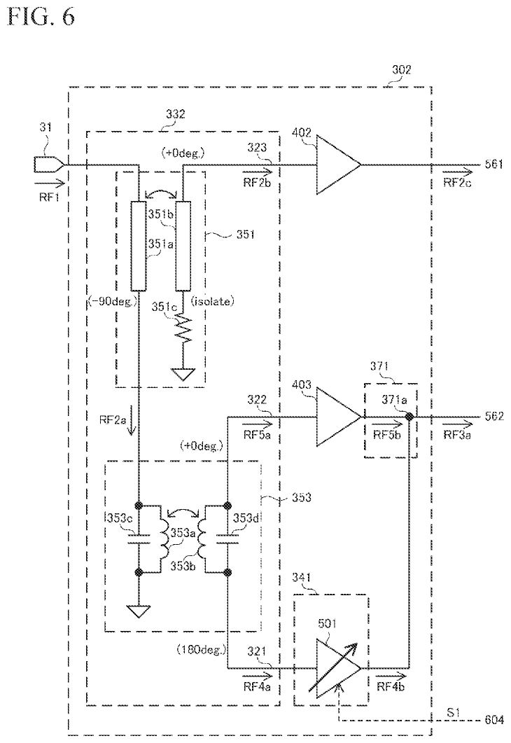

FIG. 6 is a circuit diagram of a variable power splitter circuit 302. As illustrated in FIG. 6, the variable power splitter circuit 302 according to the second embodiment differs from the variable power splitter circuit 301 according to the first embodiment in that a signal RF2a is split by a balun.

As compared to the variable power splitter circuit 301 illustrated in FIG. 1, the variable power splitter circuit 302 includes a splitter circuit 332 instead of the splitter circuit 331. The splitter circuit 332 includes a balun 353 instead of the 90-degree coupler 352, as compared to the splitter circuit 331 illustrated in FIG. 1. The balun 353 includes inductors 353a and 353b and capacitors 353c and 353d.

The splitter circuit 332 is operable to split a signal RF1 supplied through the input terminal 31 into a signal RF2b, which is substantially in phase with the signal RF1, a signal RF4a, which has a phase delayed by approximately 270 degrees relative to the phase of the signal RF2b, and a signal RF5a, which has a phase delayed by approximately 90 degrees relative to the phase of the signal RF2b.

Specifically, a first end of a wire 351b in a 90-degree coupler 351 is coupled to a third wire 323. When the signal RF1 is supplied to a first end of a wire 351a, the signals RF2a and RF2b are respectively output from a second end of the wire 351a and the first end of the wire 351b.

The balun 353 is operable to split the signal RF2a supplied from the 90-degree coupler 351 into the signals RF5a and RF4a.

Specifically, the inductor 353a in the balun 353 has a first end coupled to the second end of the wire 351a in the 90-degree coupler 351 and a second end coupled to the ground. The inductor 353b has a first end coupled to a second wire 322 and a second end coupled to the first wire 321. The inductor 353b is electromagnetically coupleable to the inductor 353a.

The capacitor 353c is provided between the first end of the inductor 353a and the second end of the inductor 353a. The capacitor 353d is provided between the first end of the inductor 353b and the second end of the inductor 353b.

When the signal RF2a is supplied to the first end of the inductor 353a, the signals RF5a and RF4a are respectively output from the first and second ends of the inductor 353b.

### Third Embodiment

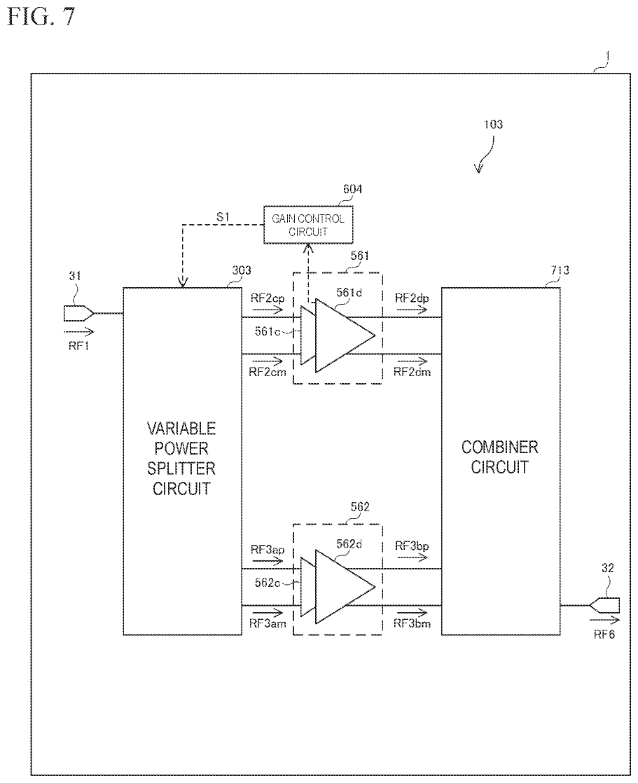

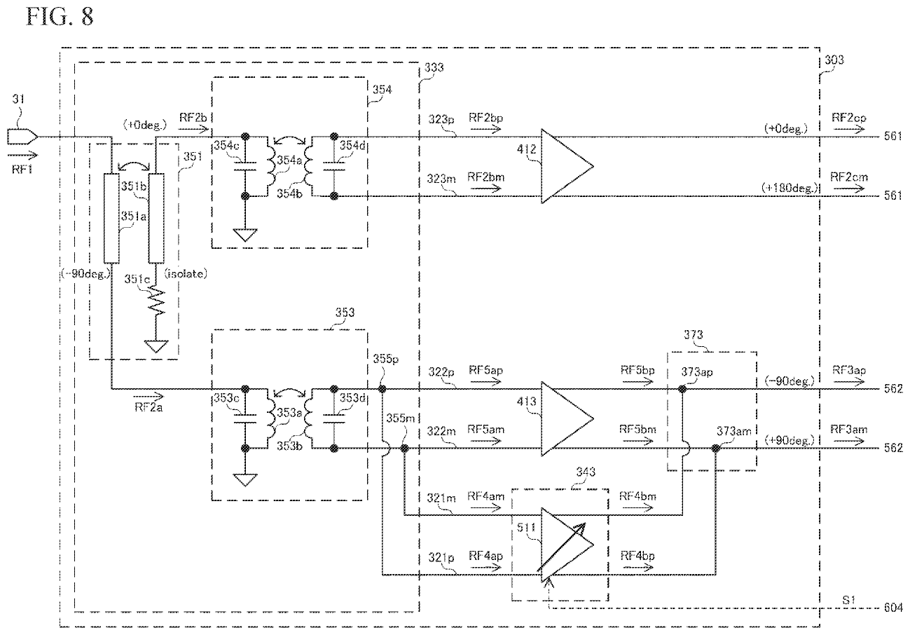

A power amplifier circuit according to a third embodiment will be described. FIG. 7 is a circuit diagram of a power amplifier circuit 103. As illustrated in FIG. 7, the power amplifier circuit 103 according to the third embodiment differs from the power amplifier circuit 101 according to the first embodiment in that a carrier circuit 561 and a peaking circuit 562 individually amplify balanced signals.

The power amplifier circuit 103 includes a variable power splitter circuit 303, the carrier circuit 561, the peaking circuit 562, a gain control circuit 604, and a combiner circuit 713. The carrier circuit 561 includes a driver-stage differential carrier amplifier 561c (carrier amplifier) and a power-stage differential carrier amplifier 561d (carrier amplifier). The power-stage differential carrier amplifier 561d is cascade-connected to the driver-stage differential carrier amplifier 561c. The peaking circuit 562 includes a driver-stage differential peaking amplifier 562c (peaking amplifier) and a power-stage differential peaking amplifier 562d (peaking amplifier). The power-stage differential peaking amplifier 562d is cascade-connected to the driver-stage differential peaking amplifier 562c.

The variable power splitter circuit 303 is operable to split a signal RF1 (first signal) into signals RF2cp (second signal) and RF2cm (second signal) and signals RF3ap (third signal) and RF3am (third signal). The signal RF1 (first signal) is an unbalanced signal. The signals RF2cp (second signal) and RF2cm (second signal) are balanced signals. The signals RF3ap (third signal) and RF3am (third signal) are balanced signals and are out of phase with the signals RF2cp (second signal) and RF2cm.

The carrier circuit 561 is operable to amplify the balanced signals, specifically the signals RF2cp and RF2cm, supplied from the variable power splitter circuit 303, by using the driver-stage differential carrier amplifier 561c and the power-stage differential carrier amplifier 561d and output signals RF2dp and RF2dm, which are amplified balanced signals, to the combiner circuit 713.

The peaking circuit 562 is operable to amplify the balanced signals, specifically the signals RF3ap and RF3am, supplied from the variable power splitter circuit 303, by using the driver-stage differential peaking amplifier 562c and the power-stage differential peaking amplifier 562d and output signals RF3bp and RF3bm, which are amplified balanced signals, to the combiner circuit 713.

The combiner circuit 713 is operable to generate an amplified signal RF6 by combining the amplified signals RF2dp and RF2dm supplied from the carrier circuit 561 and the amplified signals RF3bp and RF3bm supplied from the peaking circuit 562.

Specifically, for example, the combiner circuit 713 generates one of the balanced signals by combining the amplified signals RF2dp and RF3bp that are out of phase with each other by approximately 90 degrees; the combiner circuit 713 also generates the other of the balanced signals by combining the amplified signals RF2dm and RF3bm that are out of phase with each other by approximately 90 degrees.

The combiner circuit 713 subsequently converts the balanced signals to the amplified signal RF6 that is a single-ended signal, by using, for example, a balun.

FIG. 8 is a circuit diagram of the variable power splitter circuit 303. As illustrated in FIG. 8, the variable power splitter circuit 303 includes a splitter circuit 333, a bandpass characteristic altering circuit 343, a combiner circuit 373, and buffer amplifiers 412 and 413. The bandpass characteristic altering circuit 343 includes a canceller amplifier 511. The combiner circuit 373 includes nodes 373ap and 373am.

The splitter circuit 333 includes a 90-degree coupler 351 and baluns 353 and 354. The 90-degree coupler 351 and the balun 353 in the splitter circuit 333 are the same as the 90-degree coupler 351 and the balun 353 in the splitter circuit 332 illustrated in FIG. 6. The balun 354 includes inductors 354a and 354b and capacitors 354c and 354d.

The splitter circuit 333 is operable to split the signal RF1 supplied through the input terminal 31 into signals RF2bp (second signal) and RF2bm (second signal), signals RF4am (fourth signal) and RF4ap (fourth signal), and signals RF5ap (fifth signal) and RF5am (fifth signal). The signals RF2bp (second signal) and RF2bm (second signal) are balanced signals. The signals RF4am (fourth signal) and RF4ap (fourth signal) are balanced signals and are out of phase with the signals RF2bp and RF2bm by approximately 90 degrees. The signals RF5ap (fifth signal) and RF5am (fifth signal) are balanced signals and are substantially in antiphase with the signals RF4am and RF4ap.

Specifically, the inductor 354a in the balun 354 has a first end coupled to a first end of a wire 351b in the 90-degree coupler 351 and a second end coupled to the ground. The inductor 354b has a first end coupled to a third wire 323p and a second end coupled to a third wire 323m. The inductor 354b is electromagnetically coupleable to the inductor 354a.

The capacitor 354c is provided between the first end of the inductor 354a and the second end of the inductor 354a. The capacitor 354d is provided between the first end of the inductor 354b and the second end of the inductor 354b.

When the signal RF2b is supplied to the first end of the inductor 354a, the signals RF2bp and RF2bm are respectively output from the first and second ends of the inductor 354b. The third wire 323p and 323m are balanced lines. The third wires 323p and 323m are operable to respectively transmit the signals RF2bp and RF2bm.

The buffer amplifier 412 is a differential amplifier. The buffer amplifier 412 is operable to amplify the difference between the signals RF2bp and RF2bm supplied from the balun 354. The buffer amplifier 412 is operable to differentially output the signals RF2cp and RF2cm, which are differentially amplified balanced signals, to the carrier circuit 561.

Second wires 322p and 322m are balanced lines. The second wires 322p and 322m are respectively coupled to the first and second ends of the inductor 353b in the balun 353.

First wires 321m and 321p are balanced lines. The first wires 321m and 321p are respectively coupled to a node 355p in the second wire 322p and a node 355m in the second wire 322m.

The balun 353 is operable to convert the signal RF2a supplied by the 90-degree coupler 351 into balanced signals. The signal outputted from the first end of the inductor 353b has a phase that is delayed by approximately 90 degrees relative to the signal RF2bp. The signal outputted from the first end of the inductor 353b can be supplied as the signals RF5ap and RF4ap to the buffer amplifier 413 and the canceller amplifier 511.

The signal outputted from the second end of the inductor 353b has a phase that is delayed by approximately 90 degrees relative to the signal RF2bm. The signal outputted from the second end of the inductor 353b can be supplied as the signals RF5am and RF4am to the buffer amplifier 413 and the canceller amplifier 511.

The buffer amplifier 413 is a differential amplifier. The buffer amplifier 413 is operable to amplify the difference between the balanced signals, specifically the signals RF5ap and RF5am, supplied from the balun 353. The buffer amplifier 413 is operable to output signals RF5bp and RF5bm, which are differentially amplified balanced signals, to the nodes 373ap and 373am in the combiner circuit 373.

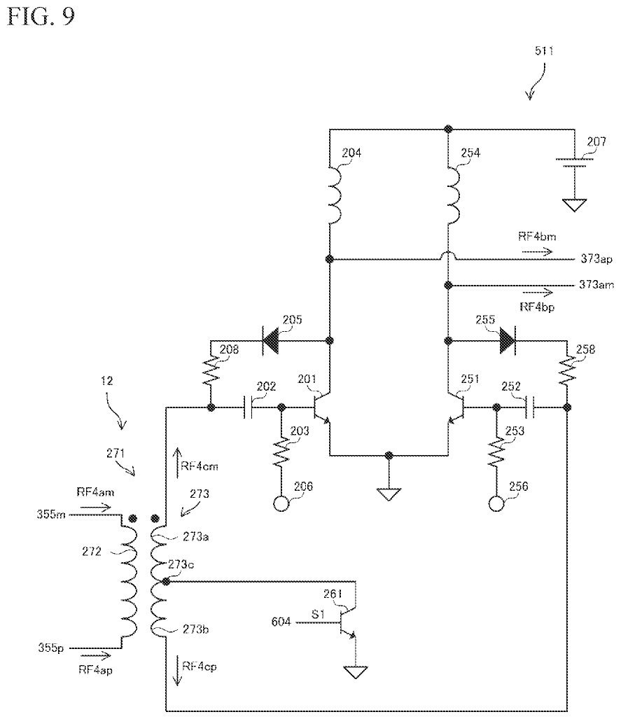

FIG. 9 is a circuit diagram of the canceller amplifier 511. As illustrated in FIG. 9, the canceller amplifier 511 is operable to amplify the difference between the signals RF4am and RF4ap and output signals RF4bm and RF4bp, which are differentially amplified balanced signals. The canceller amplifier 511 is a variable gain differential amplifier circuit. The gain of the variable gain differential amplifier circuit is variable.

The canceller amplifier 511 includes a current control circuit 12, transistors 201 and 251, capacitors 202 and 252, resistance elements 203 and 253, inductors 204 and 254, diodes 205 and 255, resistance elements 208 and 258, and a voltage supply 207.

The transistor 201, the capacitor 202, the resistance elements 203 and 208, the inductor 204, the diode 205, a bias supply terminal 206, and the voltage supply 207 in the canceller amplifier 511 are the same as the transistor 201, the capacitor 202, the resistance elements 203 and 208, the inductor 204, the diode 205, the bias supply terminal 206, and the voltage supply 207 in the canceller amplifier 501 illustrated in FIG. 2.

The current control circuit 12 includes a transistor 261 and a transformer 271. The transformer 271 includes a primary inductor 272 and a secondary inductor 273. The secondary inductor 273 includes inductors 273a and 273b.

The primary inductor 272 has a first end coupled to the node 355m and a second end coupled to the node 355p.

The inductor 273a in the secondary inductor 273 is electromagnetically coupleable to the primary inductor 272. The inductor 273a has a first end coupled to a first end of the capacitor 202 and a second end that serves as a node 273c.

The inductor 273b is electromagnetically coupleable to the primary inductor 272. The inductor 273b has a first end coupled to the second end of the inductor 273a, which serves as the node 273c, and a second end. The inductance of the inductor 273b is substantially the same as the inductance of the inductor 273a.

The transistor 261 has a collector coupled to the node 273c, a base coupled to the gain control circuit 604, and an emitter coupled to the ground.

In the transformer 271, when the signals RF4am and RF4ap are respectively supplied to the first and second ends of the primary inductor 272, signals RF4cm and RF4cp are respectively output from the first end of the inductor 273a and the second end of the inductor 273b. At this time, the signal RF4cm is out of phase with the signal RF4cp by approximately 180°.

The capacitor 252 has a first end coupled to the second end of the inductor 273b and a second end. The resistance element 253 has a first end coupled to a bias supply terminal 256 and a second end. A bias current or bias voltage from the transistor 251 can be supplied to the bias supply terminal 256.

The transistor 251 has a base coupled to the second end of the capacitor 252 and the second end of the resistance element 253, a collector coupled to a positive electrode of the voltage supply 207 via the inductor 254, and an emitter coupled to the ground.

A bias current or bias voltage can be supplied to the base of the transistor 251 from the bias supply terminal 256 through the resistance element 253. A voltage can be applied to the collector of the transistor 251 from voltage supply 207 through the inductor 254.

The diode 255 has an anode coupled to the collector of the transistor 251 and a cathode coupled to the first end of the capacitor 252 via the resistance element 258. The diode 255 may be formed by a diode-connected transistor.

The collector of the transistor 201 and the collector of the transistor 251 are respectively coupled to the nodes 373ap and 373am in the combiner circuit 373. The transistors 201 and 251 are operable to respectively amplify the signals RF4cm and RF4cp. The gain of the transistor 201 and the gain of the transistor 251 are controllable via a control signal S1 that is supplied to the base of transistor 261. In the present embodiment, when the power-stage differential carrier amplifier 561d (see FIG. 7) in the carrier circuit 561 becomes saturated, the voltage of the control signal S1 rises, and the gain of the transistors 201 and 251 decreases.

From the collector of the transistor 201, the signal RF4bm, which is the amplified signal RF4cm, is output to the node 373ap. From the collector of the transistor 251, the signal RF4bp, which is the amplified signal RF4cp, is output to the node 373ap.

As illustrated in FIG. 8, at the node 373ap in the combiner circuit 373, the signal RF5bp from the buffer amplifier 413 and the signal RF4bm from the canceller amplifier 511 can be combined. Because the phase of the signal RF5bp and the phase of the signal RF4bm are out of phase by approximately 180 degrees, when the gain of the canceller amplifier 511 decreases, cancellation of the signal RF5bp by the signal RF4bm is suppressed, and the power of the signal RF3ap transmitted from the node 373ap to the peaking circuit 562 increases.

Similarly, at the node 373am in the combiner circuit 373, the signal RF5bm from the buffer amplifier 413 and the signal RF4bp from the canceller amplifier 511 can be combined. Because the phase of the signal RF5bm and the phase of the signal RF4bp are out of phase by approximately 180 degrees, when the gain of the canceller amplifier 511 decreases, cancellation of the signal RF5bm by the signal RF4bp is suppressed, and the power of the signal RF3am transmitted from the node 373am to the peaking circuit 562 increases.

Overall, when the power-stage differential carrier amplifier 561d (see FIG. 7) in the carrier circuit 561 becomes saturated, and the gain of the canceller amplifier 511 decreases, the power of the signals RF3ap and RF3am inputted to the peaking circuit 562 increases.

With this configuration, by operating the peaking circuit 562, saturation of the power-stage differential carrier amplifier 561d can be relaxed. This configuration thus achieves a linear input-output characteristic without necessarily the power-stage differential carrier amplifier 561d in the power amplifier circuit 103 entering saturation.

### Fourth Embodiment

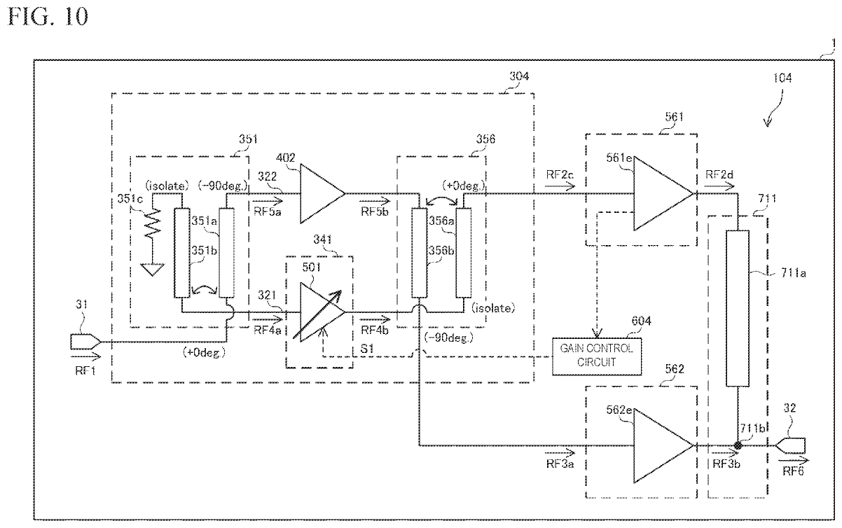

A power amplifier circuit according to a fourth embodiment will be described. FIG. 10 is a circuit diagram of a power amplifier circuit 104. As illustrated in FIG. 10, the power amplifier circuit 104 according to the fourth embodiment differs from the power amplifier circuit 101 according to the first embodiment in that the input power to the carrier amplifier is also controlled based on saturation of the carrier amplifier.

The power amplifier circuit 104 includes a variable power splitter circuit 304, a carrier circuit 561, a peaking circuit 562, a gain control circuit 604, and a combiner circuit 711. The carrier circuit 561 includes a carrier amplifier 561e (target carrier amplifier). The peaking circuit 562 includes a peaking amplifier 562e. The gain control circuit 604 and the combiner circuit 711 in the power amplifier circuit 104 are the same as the gain control circuit 604 and the combiner circuit 711 in the power amplifier circuit 101 illustrated in FIG. 1.

The variable power splitter circuit 304 is operable to increase the power (first power) of a signal RF3a (third signal) and reduce the power (second power) of a signal RF2c (second signal) in response to the control signal S1. The variable power splitter circuit 304 is also operable to reduce the power of the signal RF3a and increase the power of the signal RF2a in response to the control signal S1.

Each circuit in the variable power splitter circuit 304 will be detailed below. The variable power splitter circuit 304 includes a first wire 321, a second wire 322, a bandpass characteristic altering circuit 341, a 90-degree coupler 351 (splitter circuit), a 90-degree coupler 356 (generating circuit), and a buffer amplifier 402.

The 90-degree coupler 356 includes wires 356a and 356b. The wires 356a and 356b are, for example, quarter wavelength lines. The 90-degree coupler 351, the bandpass characteristic altering circuit 341, and the buffer amplifier 402 are the same as the 90-degree coupler 351, the bandpass characteristic altering circuit 341, and the buffer amplifier 402 in the variable power splitter circuit 301 illustrated in FIG. 1.

The 90-degree coupler 351 is operable to split a signal RF1 (first signal) into the signal RF4a (fourth signal) and a signal RF5a (fifth signal). The signal RF5a is out of phase with the signal RF4a by approximately 90 degrees.

Specifically, the wire 351a in the 90-degree coupler 351 has a first end coupled to an input terminal 31 and a second end coupled to the second wire 322. The wire 351b has a first end coupled to the first wire 321 and a second end coupled to the ground via a resistance element 351c. The wire 351b is electromagnetically coupleable to the wire 351a.

When the signal RF1 is supplied to the first end of the wire 351a, the signal RF5a, which has a phase delayed by approximately 90° relative to the signal RF1, is output from the second end of the wire 351a, and the signal RF4a, which is substantially in phase with the signal RF1, is output from the first end of the wire 351b.

The second wire 322 couples the first end of the wire 351a to the 90-degree coupler 356. The second wire 322 is operable to transmit signals RF5a and RF5b. The buffer amplifier 402 is provided in the second wire 322. The buffer amplifier 402 has an input terminal coupled to the second end of the wire 351a in the 90-degree coupler 351, and an output terminal. The signal RF5b (fifth signal) obtained by amplifying the signal RF5a supplied to the input terminal can be output from the output terminal of the buffer amplifier 402.

The first wire 321 couples the first end of the wire 351b to the 90-degree coupler 356. The first wire 321 is operable to transmit signals RF4a and RF4b. The canceller amplifier 501 in the bandpass characteristic altering circuit 341 is provided in the first wire 321. The canceller amplifier 501 has an input terminal coupled to the first end of the wire 351b in the 90-degree coupler 351, and an output terminal. The signal RF4b (fourth signal) obtained by amplifying the signal RF4a supplied to the input terminal can be output from the output terminal of the canceller amplifier 501.

The 90-degree coupler 356 is operable to generate the signal RF2c by combining the signal RF4b after passing through the first wire 321 and the signal RF5b after passing through the second wire 322 in the state in which the signals RF4b and the signal RF5b are substantially in phase with each other. The 90-degree coupler 356 is also operable to generate the signal RF3a by combining the signal RF4b after passing through the first wire 321 and the signal RF5b after passing through the second wire 322 in the state in which the signals RF4b and RF5b are substantially in antiphase with each other.

Specifically, the wire 356a in the 90-degree coupler 356 has a first end coupled to the output terminal of the canceller amplifier 501 and a second end coupled to the input terminal of the carrier amplifier 561e. The wire 356b has a first end coupled to an input terminal of the peaking amplifier 562e and a second end coupled to the output terminal of the buffer amplifier 402. The wire 356b is electromagnetically coupleable to the wire 356a.

When the signal RF4b is supplied to the first end of the wire 356a, and the signal RF5b is supplied to the second end of the wire 356b, the signals RF2c and RF3a are respectively output from the second end of the wire 356a and the first end of the wire 356b.

When the signal RF5b enters the 90-degree coupler 356, the phase of the signal RF5b is delayed by approximately 90 degrees relative to the phase of the signal RF4b. As a result, at the second end of the wire 356a, a signal based on the signal RF4b, having a phase delayed by approximately 90 degrees by the wire 356a, and a signal based on the signal RF5b are combined substantially in phase to generate the signal RF2c.

This means that when the carrier amplifier 561e becomes saturated, the gain of the canceller amplifier 501 decreases, and the power of the signal RF4b decreases, the power of the signal RF2c, that is, the input power to the carrier amplifier 561e decreases.

When saturation of the carrier amplifier 561e is resolved, the gain of the canceller amplifier 501 increases, and the power of the signal RF4b increases, the power of the signal RF2c, that is, the input power to the carrier amplifier 561e increases. In this manner, the carrier amplifier 561e can be operated while saturation is suppressed.

At the first end of the wire 356b, a signal based on the signal RF4b and a signal based on the signal RF5b, having a phase delayed by approximately 90 degrees by the wire 356b, are combined substantially in antiphase to generate the signal RF3a.

This means that when the carrier amplifier 561e becomes saturated, the gain of the canceller amplifier 501 decreases, and the power of the signal RF4b decreases, cancellation of the signal RF5b by the signal RF4b is suppressed. As a result, the power of the signal RF3a, that is, the input power to the peaking amplifier 562e increases.

When the saturation of the carrier amplifier 561e is resolved, the gain of the canceller amplifier 501 increases, and the power of the signal RF4b increases, cancellation of the signal RF5b by the signal RF4b is promoted. As a result, the power of the signal RF3a, that is, the input power to the peaking amplifier 562e decreases. In this manner, the peaking amplifier 562e can be operated while saturation of the carrier amplifier 561e is suppressed.

Further, the second end of the wire 356b serves as an isolation port with respect to the signal RF4b inputted to the first end of the wire 356a in the 90-degree coupler 356. As a result, the load on the buffer amplifier 402 does not vary depending on the output power of the signal RF4b from the canceller amplifier 501. Accordingly, variations in the gain and bandpass characteristic of the buffer amplifier 402 are suppressed. This configuration hinders distortion of the signal RF5b and improves the quality of the amplified signal RF6.

### Fifth Embodiment

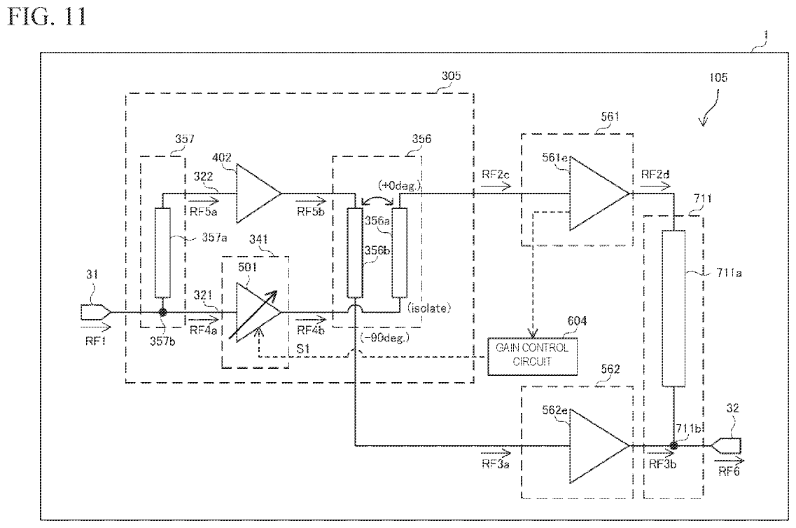

A power amplifier circuit according to a fifth embodiment will be described. FIG. 11 is a circuit diagram of a power amplifier circuit 105. As illustrated in FIG. 11, the power amplifier circuit 105 differs from the power amplifier circuit 104 according to the fourth embodiment in that the circuit for splitting the signal RF1 is simplified.

As compared to the power amplifier circuit 104 illustrated in FIG. 10, the power amplifier circuit 105 includes a variable power splitter circuit 305 instead of the variable power splitter circuit 304. As compared to the variable power splitter circuit 304 illustrated in FIG. 10, the variable power splitter circuit 305 includes a splitter circuit 357 instead of the 90-degree coupler 351. The splitter circuit 357 includes a quarter wavelength line 357a and a node 357b.

An input terminal of a canceller amplifier 501 in a bandpass characteristic altering circuit 341 is coupled to the node 357b via a first wire 321.

The quarter wavelength line 357a in the splitter circuit 357 has a first end coupled to an input terminal 31 via the node 357b and a second end coupled to an input terminal of a buffer amplifier 402.

A signal RF1 supplied to the input terminal 31 can be split into signals RF4a and RF5a at the node 357b. The signal RF4a can be input to the canceller amplifier 501 through the first wire 321. The signal RF5a can be input to the buffer amplifier 402 through the quarter wavelength line 357a and a second wire 322.

The quarter wavelength line 357a is operable to introduce a phase delay of approximately 90 degrees to the signal RF5a. As a result, the phase of the signal RF5a is delayed by approximately 90 degrees relative to the phase of the signal RF4a.

### Sixth Embodiment

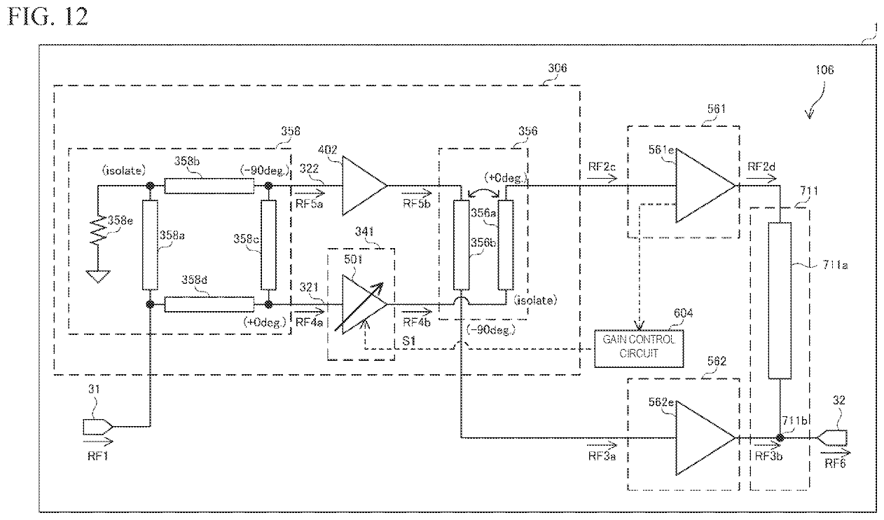

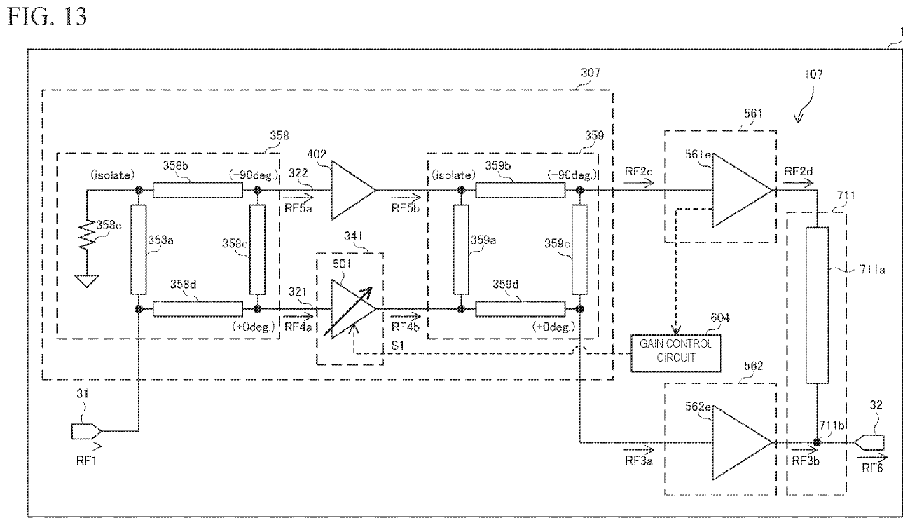

A power amplifier circuit according to a sixth embodiment will be described. FIG. 12 is a circuit diagram of a power amplifier circuit 106. As illustrated in FIG. 12, the power amplifier circuit 106 according to the sixth embodiment differs from the power amplifier circuit 104 according to the fourth embodiment in that a 90-degree branch-line coupler is used as a circuit for splitting the signal RF1.

As compared to the power amplifier circuit 104 illustrated in FIG. 10, the power amplifier circuit 106 includes a variable power splitter circuit 306 instead of the variable power splitter circuit 304. As compared to the variable power splitter circuit 304 illustrated in FIG. 10, the variable power splitter circuit 306 includes a 90-degree branch-line coupler 358 (splitter circuit) instead of the 90-degree coupler 351. The 90-degree branch-line coupler 358 includes quarter wavelength lines 358a, 358b, 358c, and 358d and a resistance element 358e.

The quarter wavelength line 358a in the 90-degree branch-line coupler 358 has a first end coupled to an input terminal 31 and a second end coupled to the ground via the resistance element 358e. The quarter wavelength line 358b has a first end coupled to the second end of the quarter wavelength line 358a and a second end coupled to an input terminal of a buffer amplifier 402.

The quarter wavelength line 358d has a first end coupled to the first end of the quarter wavelength line 358a and a second end coupled to an input terminal of a canceller amplifier 501. The quarter wavelength line 358c has a first end coupled to the second end of the quarter wavelength line 358d and a second end coupled to the second end of the quarter wavelength line 358b.

When a signal RF1 is supplied to the first end of the quarter wavelength line 358a and the first end of the quarter wavelength line 358d, a signal RF4a is output from the second end of the quarter wavelength line 358d, and a signal RF5a, which has a phase delayed by approximately 90° relative to the signal RF4a, is output from the second end of the quarter wavelength line 358b.

### Seventh Embodiment

A power amplifier circuit according to a seventh embodiment will be described. FIG. 13 is a circuit diagram of a power amplifier circuit 107. As illustrated in FIG. 13, the power amplifier circuit 107 according to the seventh embodiment differs from the power amplifier circuit 106 according to the sixth embodiment in that a 90-degree branch-line coupler is used as a circuit for generating signals RF2c and RF3a.

As compared to the power amplifier circuit 106 illustrated in FIG. 12, the power amplifier circuit 107 includes a variable power splitter circuit 307 instead of the variable power splitter circuit 306. As compared to the variable power splitter circuit 306 illustrated in FIG. 12, the variable power splitter circuit 307 includes a 90-degree branch-line coupler 359 (generating circuit) instead of the 90-degree coupler 356. The 90-degree branch-line coupler 359 includes quarter wavelength lines 359a, 359b, 359c, and 359d.

The quarter wavelength line 359a in the 90-degree branch-line coupler 359 has a first end coupled to an output terminal of a canceller amplifier 501 and a second end coupled to an output terminal of a buffer amplifier 402. The quarter wavelength line 359b has a first end coupled to the second end of the quarter wavelength line 359a and a second end coupled to an input terminal of a carrier amplifier 561e.

The quarter wavelength line 359d has a first end coupled to the first end of the quarter wavelength line 359a and a second end coupled to an input terminal of a peaking amplifier 562e. The quarter wavelength line 359c has a first end coupled to the second end of the quarter wavelength line 359d and a second end coupled to the second end of the quarter wavelength line 359b.

When a signal RF4b is supplied to the first end of the quarter wavelength line 359a and the first end of the quarter wavelength line 359d from the canceller amplifier 501, the signal RF3a is output from the second end of the quarter wavelength line 359d, and the signal RF2c, which has a phase delayed by approximately 90° relative to the signal RF3a, is output from the second end of the quarter wavelength line 359b.

When a signal RF5b enters the 90-degree branch-line coupler 359, the phase of the signal RF5b is delayed by approximately 90 degrees relative to the phase of the signal RF4b. As a result, at the second end of the quarter wavelength line 359b, a signal based on the signal RF4b, having a phase delayed by approximately 180 degrees by the quarter wavelength lines 359a and 359b or the quarter wavelength lines 359d and 359c, and a signal based on the signal RF5b, having a phase delayed by approximately 90 degrees by the quarter wavelength line 359b, are combined substantially in phase to generate the signal RF2c.

At the second end of the quarter wavelength line 359d, a signal based on the signal RF4b, having a phase delayed by approximately 90 degrees by the quarter wavelength line 359d, and a signal based on the signal RF5b, having a phase delayed by approximately 180 degrees by the quarter wavelength lines 359a and 359d or the quarter wavelength lines 359b and 359c are combined substantially in antiphase to generate the signal RF3a.

### Eighth Embodiment

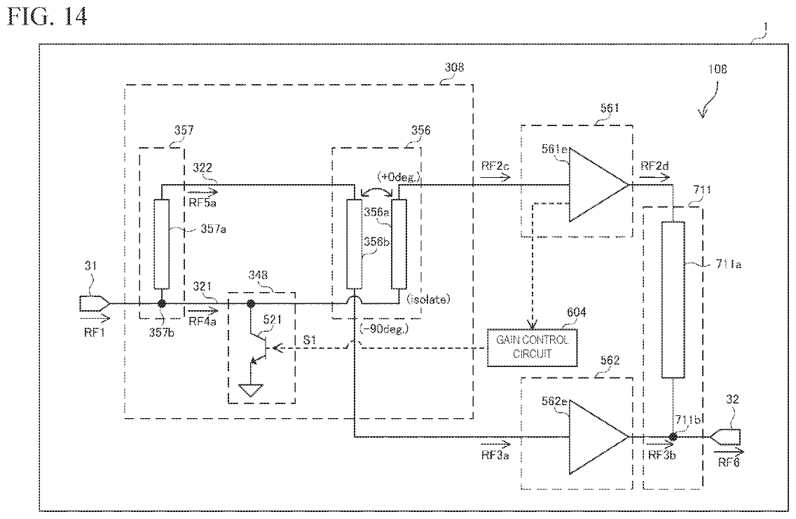

A power amplifier circuit according to an eighth embodiment will be described. FIG. 14 is a circuit diagram of a power amplifier circuit 108. As illustrated in FIG. 14, the power amplifier circuit 108 according to the eighth embodiment differs from the power amplifier circuit 105 according to the fifth embodiment in that the bandpass characteristic altering circuit for altering the bandpass characteristic of the first wire 321 is simplified.

As compared to the power amplifier circuit 105 illustrated in FIG. 11, the power amplifier circuit 108 includes a variable power splitter circuit 308 instead of the variable power splitter circuit 305. As compared to the variable power splitter circuit 305 illustrated in FIG. 11, the variable power splitter circuit 308 includes a bandpass characteristic altering circuit 348 instead of the bandpass characteristic altering circuit 341 and the buffer amplifier 402. The bandpass characteristic altering circuit 348 includes a transistor 521 (variable resistance element). Alternatively to a transistor, a diode or varicap diode (variable capacitance) may be used as a variable resistance element.

An input terminal 31 is coupled to a first end of a quarter wavelength line 357a in a splitter circuit 357 via a node 357b. A second end of a wire 356b in a 90-degree coupler 356 is coupled to a second end of the quarter wavelength line 357a via a second wire 322.

A first end of a wire 356a in the 90-degree coupler 356 is coupled to the node 357b in the splitter circuit 357 via a first wire 321.

The transistor 521 in the bandpass characteristic altering circuit 348 is provided between the first wire 321 and the ground. The equivalent resistance of the transistor 521 is variable in response to the control signal S1.

Specifically, the transistor 521 has a collector coupled to the first end of the quarter wavelength line 357a and the first end of the wire 356a, a base coupled to a gain control circuit 604, and an emitter coupled to the ground.

When a carrier amplifier 561e is not saturated, the voltage of the control signal S1 is relatively low. As a result, the equivalent resistance across the collector and the emitter of the transistor 521 is relatively high. By contrast, when the carrier amplifier 561e becomes saturated, the voltage of the control signal S1 increases, and the equivalent resistance across the collector and the emitter of the transistor 521 decreases.

This means that when the carrier amplifier 561e becomes saturated, the power of a signal RF4a inputted to the first end of the wire 356a is relatively low; when saturation of the carrier amplifier 561e is resolved, the power of the signal RF4a is relatively high.

At the second end of the wire 356a in the 90-degree coupler 356, a signal based on the signal RF4a and a signal based on the signal RF5a can be combined substantially in phase. By contrast, at the first end of the wire 356b, a signal based on the signal RF4a and a signal based on the signal RF5a can be combined substantially in antiphase.

As a result, when the carrier amplifier 561e becomes saturated, the input power to the carrier amplifier 561e increases, and the input power to the peaking amplifier 562e increases. When saturation of the carrier amplifier 561e is resolved, the input power to the carrier amplifier 561e increases, and the input power to the peaking amplifier 562e decreases.

The foregoing has described the configurations in which in the variable power splitter circuits 301, 302, 304, 305, 306, and 307, the bandpass characteristic altering circuit 341 alters the bandpass characteristic of the signal RF4a while passing through the first wire 321 by changing the gain of the canceller amplifier 501. However, this is not to be interpreted as limiting. For example, a switch or attenuator may be provided in the first wire 321 to alter the bandpass characteristic of the signal RF4a while passing through the first wire 321. The same applies to the variable power splitter circuit 303.

The exemplary embodiments of the present disclosure have been described above. In the power amplifier circuit 101, the variable power splitter circuit 301 is configured to split the signal RF1 into the signal RF2c and the signal RF3a, which is out of phase with the signal RF2c, and to increase or decrease the power of the signal RF3a in response to the control signal S1. The carrier circuit 561 includes one or more carrier amplifiers. The carrier circuit 561 is configured to amplify the signal RF2c and output the signal RF2c that has been amplified, that is, the amplified signal RF2d. The peaking circuit 562 includes one or more peaking amplifiers. The peaking circuit 562 is configured to amplify the signal RF3a and output the signal RF3a that has been amplified, that is, the amplified signal RF3b. The gain control circuit 604 is configured to output the control signal S1 to the variable power splitter circuit 301, based on the saturation level of the target carrier amplifier 561b, which is positioned closest to the output among the one or more carrier amplifiers in the carrier circuit 561.

As described above, the power of the signal RF3a inputted to the peaking circuit 562 is increased or decreased based on the saturation level of the target carrier amplifier 561b. This configuration provides control for amplification of the peaking amplifier without necessarily increasing the bandpass characteristic of the peaking amplifier. This configuration thus reduces the likelihood that the amplified signal RF2d from the carrier circuit 561 pass through the closed circuit including the peaking amplifier and re-enter the carrier circuit 561. Accordingly, this configuration reduces the likelihood that the power amplifier circuit 101 operate as an oscillation circuit. This configuration also reduces the likelihood that although the power amplifier circuit 101 does not operate as an oscillation circuit, the power amplifier circuit 101 fail to achieve optimum performance as a result of overlapping of a portion of the amplified signal RF2d that has passed through the closed circuit and the input signal to the target carrier amplifier 561b. The present disclosure therefore provides the power amplifier circuit capable of achieving a linear input-output characteristic, while suppressing the increase in the bandpass characteristic of the peaking amplifier.

In the power amplifier circuit 104, the variable power splitter circuit 304 is configured to increase the power of the signal RF3a and decreases the power of the signal RF2c in response to the control signal S1, or decrease the power of the signal RF3a and increase the power of the signal RF2c in response to the control signal S1.

With this configuration, when the target carrier amplifier 561e becomes saturated, the input power to the target carrier amplifier 561e immediately decreases. As such, saturation of the target carrier amplifier 561e can be relaxed. When saturation of the target carrier amplifier 561e is resolved, the input power to the target carrier amplifier 561e immediately increases. The target carrier amplifier 561e thus quickly returns to normal amplification operation. As a result, distortion of the amplified signal RF6 outputted from the power amplifier circuit 104, caused by saturation of the target carrier amplifier 561e, can be suppressed. This configuration thus improves the quality of the amplified signal RF6.

In the power amplifier circuit 103, the variable power splitter circuit 303 is configured to split the signal RF1, which is an unbalanced signal, into the signals RF2cp and RF2cm, which are balanced signals, and the signals RF3ap and RF3am, which are balanced signals and are respectively out of phase with the signals RF2cp and RF2cm. The driver-stage differential carrier amplifier 561c and the power-stage differential carrier amplifier 561d, and the driver-stage differential peaking amplifier 562c and the power-stage differential peaking amplifier 562d are all differential amplifiers.

With this configuration, a single-ended signal can be converted into balanced signals and amplified. As a result, this configuration increases the output of the power amplifier circuit 103 and enhances noise immunity. This enhancement of noise immunity eliminates a need for optimum ground and power lines, which are suitable when noise immunity is low. As a result, the wiring for the ground and the bypass capacitor for the power lines can be simplified. The neutralization technique described in Non Patent Document 1 may be applied to the differential amplifiers.

In the power amplifier circuit 101, the variable power splitter circuit 301 includes the splitter circuit 331 for splitting the signal RF1 into the signal RF2b, the signal RF4a, which is out of phase with the signal RF2b by approximately 90 degrees, and the signal RF5a, which is substantially in antiphase with the signal RF4a, the first wire 321 and the second wire 322 for respectively transmitting the signals RF4a and RF5a from the splitter circuit 331, the bandpass characteristic altering circuit 341 for altering the bandpass characteristic of the signal RF4a while passing through the first wire 321 in response to the control signal S1, and the combiner circuit 371 for generating the signal RF3a by combining the signal RF4a after passing through the first wire 321 and the signal RF5a after passing through the second wire 322.

As described above, the bandpass characteristic of the first wire 321, which is provided separately from the closed circuit formed by the carrier circuit 561, the peaking circuit 562, the second wire 322, and the third wire 323, can be altered. This configuration effectively reduces the likelihood that the closed circuit serve as an oscillation circuit. This configuration also effectively reduces the likelihood that although the closed circuit does not operate as an oscillation circuit, the power amplifier circuit 101 fail to achieve optimum performance as a result of overlapping of a portion of the output from the carrier amplifier that has passed through the closed circuit and the input signal to the carrier amplifier.

In the power amplifier circuit 104, the variable power splitter circuit 304 includes the 90-degree coupler 351 for splitting the signal RF1 into the signal RF4a and the signal RF5a, which is out of phase with the signal RF4a by approximately 90 degrees, the first wire 321 and the second wire 322 for respectively transmitting the signals RF4a and RF5a from the 90-degree coupler 351, the bandpass characteristic altering circuit 341 for altering the bandpass characteristic of the signal RF4a while passing through the first wire 321 in response to the control signal S1, and the 90-degree coupler 356 for generating the signal RF2c by combining the signal RF4a after passing through the first wire 321 and the signal RF5a after passing through the second wire 322 in the state in which the signals RF4a and RF5a are substantially in phase and for generating the signal RF3a by combining the signal RF4a after passing through the first wire 321 and the signal RF5a after passing through the second wire 322 in the state in which the signals RF4a and RF5a are substantially in antiphase.

As described above, the bandpass characteristic of the first wire 321, which is provided separately from the closed circuit formed by the carrier circuit 561, the peaking circuit 562, and the 90-degree coupler 356, can be altered. This configuration effectively reduces the likelihood that the closed circuit serve as an oscillation circuit. This configuration also effectively reduces the likelihood that although the closed circuit does not operate as an oscillation circuit, the power amplifier circuit 104 fail to achieve optimum performance as a result of overlapping of a portion of the output from the carrier amplifier that has passed through the closed circuit and the input signal to the carrier amplifier.

In the power amplifier circuit 101, the bandpass characteristic altering circuit 341 includes the canceller amplifier 501 provided in the first wire 321. The gain of the canceller amplifier 501 is variable in response to the control signal S1.

With this configuration, while the isolation between the anterior stage and the posterior stage of the canceller amplifier 501 is secured, the bandpass characteristic of the signal RF4a transmitted through the first wire 321 can be altered.

In the power amplifier circuit 101, the gain control circuit 604 is configured to, when the target carrier amplifier 561b becomes saturated, output to the variable power splitter circuit 301 the control signal S1 for reducing the gain of the canceller amplifier 501.

With this configuration, when the amount of heat generation by the target carrier amplifier 561b increases due to saturation, the amount of heat generation by the canceller amplifier 501 as a control target can be reduced. This configuration thus suppresses the temperature rise in the control target. When the temperature of the canceller amplifier 501 is increased by heat conducted from the target carrier amplifier 561b, the temperature rise further decreases the gain of the canceller amplifier 501. As a result, the output power from the peaking circuit 562 is further increased. With this configuration, relaxation of saturation of the target carrier amplifier 561b is further promoted. This configuration thus shortens the time to stably resolve saturation of the target carrier amplifier 561b and also inhibits the target carrier amplifier 561b from becoming saturated again. The control to reduce the gain of the canceller amplifier 501 suppresses the increase in power consumption in the power amplifier circuit 101, hindering thermal runaway in the power amplifier circuit 101. This configuration thus inhibits damage to the power amplifier circuit 101.

In the power amplifier circuit 108, the bandpass characteristic altering circuit 348 includes the transistor 521 provided between the first wire 321 and the ground. The equivalent resistance of the transistor 521 is variable in response to the control signal S1.

With this configuration, the bandpass characteristic of the signal RF4a transmitted through the first wire 321 can be altered with a simple circuit configuration.

The power amplifier device includes the compound semiconductor 1 that has the semiconductor elements included in the power amplifier circuits 101 to 108.

With this configuration, control of the gain of the canceller amplifier 501 and detection of saturation of the target carrier amplifier 561b can be performed with analog signals without necessarily using digital signals. This configuration enables control without necessarily performing processing such as data conversion or calculation. As a result, for example, the operations from saturation detection of the target carrier amplifier 561b to gain control of the canceller amplifier 501 can be completed in a considerably short time. As a result, the time that the target carrier amplifier 561b remains saturated can be shortened. As such, this configuration suppresses deterioration of the quality of the amplified signal. Because the semiconductor elements are formed in the same compound semiconductor 1, the transmission distance of signals exchanged between the semiconductor elements can be shortened, so that higher-speed control can be provided.

The embodiments described above have been made for ease of understanding the present disclosure and should not be interpreted as limiting. The present disclosure may be changed or improved without necessarily departing from its spirit, and the present disclosure also includes equivalents thereof. In other words, design alterations to the individual embodiments made in any manner by those skilled in the art fall within the scope of the present disclosure, provided that the alterations retain the features of the present disclosure. For example, the features of the embodiments including individual elements, arrangement, material, condition, shape, and size, are not limited to the illustrative examples described above and can be altered in any appropriate manner. The embodiments described above are merely examples, and as might be expected, the configurations described in the different embodiments may be partially replaced or combined with each other. These modifications are embraced within the scope of the present disclosure when these modifications contain the attributes of the present disclosure.

### REFERENCE SIGNS LIST

1 compound semiconductor
31 input terminal
32 output terminal
101, 103, 104, 105, 106, 107, 108 power amplifier circuit
301, 302, 303, 304, 305, 306, 307, 308 variable power splitter circuit
321, 321p, 321m first wire
322, 322p, 322m second wire
323, 323p, 323m third wire
331, 332, 333 splitter circuit
341, 343, 348 bandpass characteristic altering circuit
351, 352 90-degree coupler
353, 354 balun
356 90-degree coupler
357 splitter circuit
358, 359 90-degree branch-line coupler
371, 373 combiner circuit
402, 403, 412, 413 buffer amplifier
501, 511 canceller amplifier
521 transistor
561 carrier circuit
562 peaking circuit
711, 713 combiner circuit

1. A power amplifier circuit comprising:
a variable power splitter circuit configured to split a first signal into a second signal and a third signal, the third signal being out of phase with the second signal, and to increase or decrease a first power of the third signal in response to a control signal;
a carrier circuit comprising one or more carrier amplifiers, the carrier circuit being configured to amplify the second signal and to output the amplified second signal;
a peaking circuit comprising one or more peaking amplifiers, the peaking circuit being configured to amplify the third signal and to output the amplified third signal; and
a control circuit configured to output the control signal to the variable power splitter circuit based on a saturation level of a target carrier amplifier, the target carrier amplifier being the carrier amplifier that is closest to an output.

2. The power amplifier circuit according to claim 1, wherein the variable power splitter circuit is configured to increase the first power and decrease a second power of the second signal in response to the control signal, or to decrease the first power and increase the second power in response to the control signal.

3. The power amplifier circuit according to claim 1,
wherein the variable power splitter circuit is configured to split the first signal into the second signal and the third signal, the first signal being an unbalanced signal, the second signal being a balanced signal, the third signal being a balanced signal, the third signal being out of phase with the second signal, and
wherein the carrier amplifier and the peaking amplifier are differential amplifiers.

4. The power amplifier circuit according to claim 1, wherein the variable power splitter circuit comprises:
a splitter circuit configured to split the first signal into the second signal, a fourth signal, and a fifth signal, the fourth signal being out of phase with the second signal by approximately 90 degrees, the fifth signal being substantially in antiphase with the fourth signal;
a first wire and a second wire that are configured to respectively transmit the fourth signal and the fifth signal from the splitter circuit;
a bandpass characteristic altering circuit configured to, in response to the control signal, alter a bandpass characteristic of the fourth signal while passing through the first wire; and
a combiner circuit configured to generate the third signal by combining the fourth signal and the fifth signal after the fourth signal passes through the first wire and after the fifth signal passes through the second wire.

5. The power amplifier circuit according to claim 2, wherein the variable power splitter circuit comprises:
a splitter circuit configured to split the first signal into the fourth signal and the fifth signal, the fifth signal being out of phase with the fourth signal by approximately 90 degrees;
a first wire and a second wire that are configured to respectively transmit the fourth signal and the fifth signal from the splitter circuit;
a bandpass characteristic altering circuit configured to, in response to the control signal, alter a bandpass characteristic of the fourth signal while passing through the first wire; and
a generating circuit configured to:
generate the second signal by combining the fourth signal and the fifth signal after the fourth signal passes through the first wire and after the fifth signal passes through the second wire when the fourth signal and the fifth signal are substantially in phase with each other, and
generate the third signal by combining the fourth signal and the fifth signal after the fourth signal passes through the first wire and after the fifth signal passes through the second wire when the fourth signal and the fifth signal are substantially antiphase with each other.

6. The power amplifier circuit according to claim 4, wherein the bandpass characteristic altering circuit comprises a variable gain amplifier in series with the first wire, the variable gain amplifier having a gain that is variable in response to the control signal.

7. The power amplifier circuit according to claim 6, wherein the control circuit is configured to, when the target carrier amplifier becomes saturated, output the control signal to the variable power splitter circuit to reduce the gain.

8. The power amplifier circuit according to claim 4, wherein the bandpass characteristic altering circuit comprises a variable resistance circuit element between the first wire and ground, the variable resistance circuit element having a resistance that is variable in response to the control signal.

9. A power amplifier device comprising a compound semiconductor that comprises semiconductor elements included in the power amplifier circuit according to any one of claim 1.
